(19) United States
(12) Patent Application Publication
(10) Pub. No.: US 2021/0176871 A1
(43) Pub. Date: Jun. 10, 2021

(54) ELECTRONIC DEVICE

(71) Applicant: BOE TECHNOLOGY GROUP CO., LTD., Beijing (CN)

(72) Inventors: Yan REN, Beijing (CN); Lei CAO, Beijing (CN); Deli FANG, Beijing (CN); Huijun LI, Beijing (CN); Junshi ZHOU, Beijing (CN)

(21) Appl. No.: 16/768,560

(22) PCT Filed: Oct. 14, 2019
(86) PCT No.: PCT/CN2019/111042

§ 371 Date: May 29, 2020

(30) Foreign Application Priority Data
Oct. 26, 2018 (CN) 201821746598.9

(51) Int. Cl. H05K 5/00; H05K 5/02

(52) U.S. Cl. CPC H05K 5/0017; H05K 5/0217

(57) ABSTRACT

The present disclosure provides an electronic device. The electronic device comprises: a frame; and a display unit surrounded by the frame on a periphery thereof. The frame comprises: an inner frame having a front surface, a back surface opposite the front surface, and a side surface connected between the front surface and the back surface; and an outer frame arranged around the side surface of the inner frame. The inner frame and outer frame are detachably engaged through at least one clamping structure.

### TECHNICAL FIELD

The present application relates to, without being limited to, the field of display technology, in particular, to an electronic device.

### BACKGROUND

An electronic picture frame (picture screen) is a display device capable of continuously displaying the contents of paintings, and can truly simulate the appearance of paintings and be viewed as the paintings, thereby integrating artistic exhibition, appreciation, transmission and the like into a whole.

The electronic picture frame may include a display panel and a wooden frame outside the side surface of the display panel. With wood appearance, the electronic picture frame serves to simulate the painting frame and endows the picture within the electronic frame a more real painting look.

The existing display panel is connected with the wooden frame through screws arranged on the back surface, but the screw connection structure is complex, and the operations required for mounting and dismounting the screws are also complex.

### SUMMARY

The present disclosure has been accomplished in order to at least partially solve the problems in the related art. The present disclosure provides an electronic device that can simplify the connection structure and operation while ensuring connection stability.

According to an aspect of the present disclosure, there is provided an electronic device including:

a frame; and

a display unit surrounded by the frame on a periphery thereof,

wherein the frame includes:

an inner frame having a front surface, a back surface opposite the front surface, and a side surface connected between the front surface and the back surface; and

an outer frame arranged around the side surface of the inner frame:

wherein the inner frame and outer frame are detachably engaged through at least one clamping structure.

In some embodiments, each of the at least one clamping structure includes a protrusion disposed on the side surface of the inner frame and a groove disposed at an inner side of the outer frame and configured to receive the protrusion.

In some embodiments, the at least one clamping structure includes an elastic clamping structure and an inelastic clamping structure, and

the elastic clamping structure enables the protrusion of the elastic clamping structure to enter into or be released from the corresponding groove through elastic deformation.

In some embodiments, the inner frame includes a middle frame located in an edge region of the front surface of the inner frame and a back case located on the back surface of the inner frame.

In some embodiments, the inelastic clamping structure includes a first clamping structure having:

a first protrusion disposed on the side surface of the inner frame, having a first side surface on the front surface side and a second side surface on the back surface side, the second side surface being parallel to the front surface, an angle between the first side surface and the second side surface being greater than 0 degree and less than 90 degrees; and

a first groove provided at the inner side of the outer frame and configured to receive the first protrusion, the first groove having a first face at the front surface side and a second face at the back surface side when assembled, the second face being parallel to and in surface contact with the second side surface when assembled.

In some embodiments, the angle between the first side surface and the second side surface is 30 to 60 degrees, and

the first face is parallel to the second face and has a gap with the first side surface when assembled.

In some embodiments, the back case includes side portions located on the side surfaces of the inner frame, and the first protrusions is disposed on a side of the side portion facing the outer frame when assembled.

In some embodiments, the outer frame includes a snap-fit portion that snaps into an upper surface of the middle frame when assembled.

In some embodiments, a first convex portion is provided on a lower surface of the snap-fit portion, and a first concave portion is provided in an upper surface of the middle frame, the first convex portion being received in the first concave portion when assembled, the first convex portion being elastically deformable.

In some embodiments, a second convex portion is provided on the second side surface, and a second concave portion is provided in the second face, the second convex portion being received in the second concave portion when assembled.

In some embodiments, the elastic clamping structure includes a second clamping structure located on the side surface of the inner frame, the second clamping structure including:

a first bent portion having a first end and a second end, the first end being connected to the middle frame:

a second protrusion that is disposed on a side, facing the outer frame, of the second end of the first bent portion when assembled, the second protrusion having a third side surface on the front surface side and a fourth side surface on the back surface side, an angle between the third side surface and the fourth side surface being 40 to 90 degrees, an angle between the fourth side surface and the front surface being 0 to 25 degrees; and

a second groove that is disposed at the inner side of the outer frame and configured to receive the second protrusion, the second groove having a third face on the front surface side and a fourth face on the back surface side when assembled, the third face being parallel to the third side surface when assembled, the fourth face being parallel to the fourth side surface when assembled.

In some embodiments, the first bent portion is elastically deformable and formed of a shape-memory material.

In some embodiments, the elastic clamping structure includes a third clamping structure located on the side surface of the inner frame, the third clamping structure including:

a second bent portion having a first end and a second end, the first end being connected to the middle frame

a third protrusion that is disposed on a side, facing the outer frame, of the second end of the second bent portion when assembled, the third protrusion having a fifth side surface on the front surface side and a sixth side surface on the back surface side, the sixth side surface being parallel to the front surface; and

a third groove that is disposed at the inner side of the outer frame and configured to receive the third protrusion, the third groove having a fifth face on the front surface side and a sixth face on the back surface side when assembled, the sixth face being parallel to and in surface contact with the sixth side surface when assembled, the fifth face having a gap with the fifth side surface when assembled.

In some embodiments, the second bent portion is elastically deformable and formed of a shape-memory material.

In some embodiments, a first opening is disposed at a portion of the back case corresponding to the second bent portion, and the second end of the second bent portion includes a protruding portion protruding from the sixth side surface toward the first opening.

In some embodiments, the frame further includes a closure member, the closure member being formed of an elastic material and including:

a base configured to close the first opening;

a major protrusion arranged on one side of the base, the major protrusion having an arrow structure disposed at an end away from the base, a dimension of the arrow structure in a direction perpendicular to a height direction of the major protrusion may be increased or reduced through elastic deformation; and

a minor protrusion arranged on the same side of the base as the major protrusion, the minor protrusion having a curved portion disposed at an end away from the base.

In some embodiments, the back case has a second opening into which the arrow structure of the major protrusion is inserted through elastic deformation, so that the back case is sandwiched between the curved portion of the minor protrusion and the base.

In some embodiments, the side edge of the inner frame includes a first side edge, two second side edges connected to two ends of the first side edge, respectively, and a third side edge connected between the two second side edges and disposed opposite the first side edge; wherein

the first clamping structure is disposed at the first side edge;

the second clamping structure is disposed at the second side edge; and

the third clamping structure is disposed at the third side edge.

In some embodiments, the inner frame is formed of a plastic or metal material.

In some embodiments, the outer frame is formed of wood or plastic.

In some embodiments, the edges of the display unit are fixed to the middle frame through a pressing piece.

In some embodiments, the middle frame is formed of a first middle frame and a second middle frame, the first middle frame being partially overlapping with the second middle frame, and one end portion of the second middle frame protrudes from one end portion of the first middle frame.

In some embodiments, the middle frame and the back case enclose a space having an opening, and the display unit is received in the space.

In some embodiments, the middle frame has a rectangular shape, a microphone is disposed on a short edge of the middle frame, and an infrared sensor and a light sensor are disposed on a long edge of the middle frame.

### BRIEF DESCRIPTION OF DRAWINGS

FIG. 1 is a schematic structural view illustrating an electronic device according to an exemplary embodiment of the present disclosure;

FIG. 2a is a schematic structural view illustrating a partial cross-section cut along line A-A′ shown in FIG. 1;

FIG. 2b is another schematic structural view illustrating a partial cross-section cut along line A-A′ shown in FIG. 1;

FIG. 3 is a schematic structural view illustrating a partial cross-section of a frame according to an exemplary embodiment of the present disclosure where a first clamping structure is clamped:

FIG. 4 is a schematic view illustrating a partial structure of a first protrusion in a frame according to an exemplary embodiment of the present disclosure;

FIG. 5 is a schematic view illustrating a partial structure of a first groove in a frame according to an exemplary embodiment of the present disclosure;

FIG. 6 is a schematic structural diagram illustrating a partial cross-section cut along line B-B′ shown in FIG. 1:

FIG. 7 is a schematic structural view illustrating a partial cross-section of a second protrusion in a frame according to an exemplary embodiment of the present disclosure;

FIG. 8 is a schematic view illustrating a partial structure of a second protrusion in a frame according to an exemplary embodiment of the present disclosure:

FIG. 9 is a schematic view illustrating a partial structure of a second groove in a frame according to an exemplary embodiment of the present disclosure:

FIG. 10 is a schematic structural view illustrating a partial cross-section cut along line C-C′ shown in FIG. 1;

FIG. 11 is a schematic view illustrating a partial structure of a third protrusion in a frame according to an exemplary embodiment of the present disclosure;

FIG. 12 is a schematic view illustrating a partial structure of a third groove in a frame according to an exemplary embodiment of the present disclosure:

FIG. 13 is a schematic view illustrating a partial structure of a first opening in a frame according to an exemplary embodiment of the present disclosure;

FIG. 14 is a schematic front view illustrating a structure of a closure member in a frame according to an exemplary embodiment of the present disclosure;

FIG. 15 is a schematic side view illustrating a structure of a closure member in a frame according to an exemplary embodiment of the present disclosure:

FIG. 16 is a schematic structural view illustrating a frame according to an exemplary embodiment of the present disclosure in which the closure member is clamped at the first opening; and

FIG. 17 is a schematic structural view illustrating an inner frame of a frame according to an exemplary embodiment of the present disclosure;

FIG. 18 is a schematic view illustrating a structure of a display unit fixed on a middle frame according to an exemplary embodiment of the present disclosure;

FIG. 19 is a schematic structural view illustrating a display unit receiving space formed of a middle frame and a back case according to an exemplary embodiment of the present disclosure; and

FIG. 20 is a schematic structural view illustrating a microphone and a sensor disposed on a middle frame according to an exemplary embodiment of the present disclosure.

### DETAILED DESCRIPTION

To make a person skilled in the art better understand the technical solutions of the present disclosure, the present disclosure will be further described in detail in conjunction with the accompany drawings and embodiments.

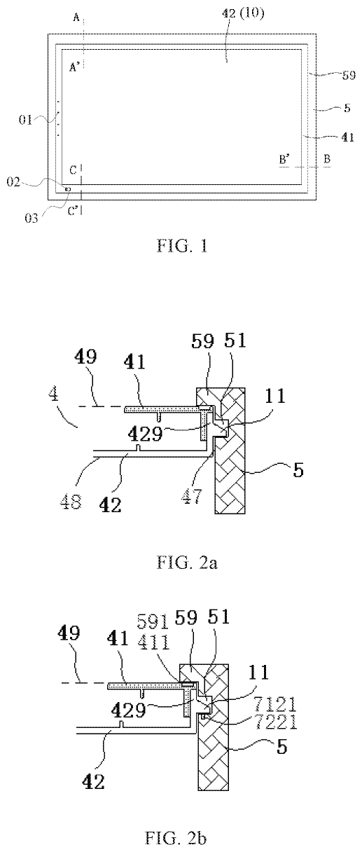

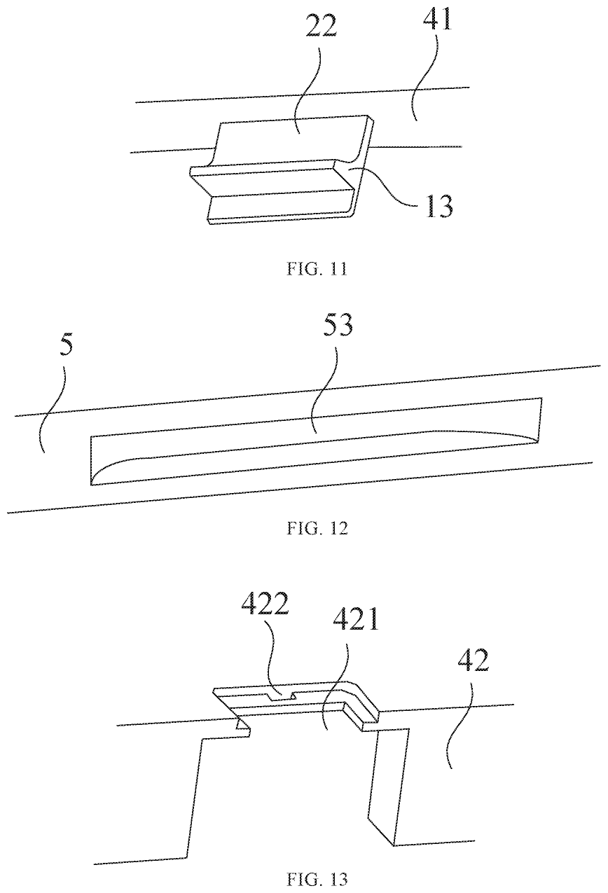

According to an aspect of the present disclosure, referring to FIGS. 1-17, an exemplary embodiment of the present disclosure provides an electronic device, including:

a frame; and

a display unit 10 surrounded by the frame on a periphery thereof,

wherein the frame includes: an inner frame 4 having a front surface 49, a back surface 48 opposite the front surface, and a side surface 47 connected between the front surface 49 and the back surface 49, for fixing a target structure;

an outer frame 5 arranged around the side surface 47 of the inner frame 4:

wherein the inner frame 4 and the outer frame 5 are detachably engaged by at least one clamping structure.

Referring to FIG. 1 and FIG. 2a, the frame provided by the exemplary embodiments of the present disclosure includes an inner frame 4 in which a target structure such as a display unit 10 may be fixed, and the inner frame 4 is clamped at an inner side of the outer frame 5, in this way, the target structure is provided in the frame. Since the inner frame 4 and the outer frame 5 are connected by clamping, the structure is simple and the operation for assembly and disassembly is also simple and convenient.

In the mean time, structures such as screws are not seen from outside of the clamping structure, thus the mechanic sense of the product (electronic picture frame) would be attenuated, and an artistic and cultural favor would be advanced, promoting the artistic quality of the product.

Of course, the inner frame 4 (including the middle frame 41 and the back case 42 described hereinafter) may be formed of conventional plastic or metal material; while the outer frame 5 may be formed of wood (thus becoming a wooden frame), or may also be formed of plastic and the like.

Of course, the connection between the inner frame 4 and the target structure may be detached. That is, the target structure and the inner frame 4 are two relatively independent members. For example, they may be the display unit and the case of the display unit, respectively. When the two members are assembled, they may constitute a display member to perform display.

In an alternative embodiment, the inner frame 4 and the target structure may be fixedly connected in a non-detachable manner, so that the inner frame 4 and the target structure together constitute a relatively independent non-detachable member.

In an exemplary embodiment of the present disclosure, each of the at least clamping structure includes a protrusion provided on a side surface 47 of the inner frame 4, and a groove provided at an inner side of the outer frame 5 for receiving the protrusion.

In an exemplary embodiment of the present disclosure, the clamping structure is divided into an elastic clamping structure and an inelastic clamping structure. The elastic clamping structure can enable the protrusion of the elastic clamping structure to enter into or be released from the corresponding groove through elastic deformation.

That is to say, each of the at least clamping structure may include a protrusion provided on a side surface 47 of the inner frame 4, and a groove provided at an inner side of the outer frame 5 for the protrusion to enter, the protrusion and the groove are used cooperatively, that is, when the protrusion enters a corresponding groove, the inner frame 4 and the outer frame 5 are clamped together (assembled), whereas when the protrusion is released from the groove, the inner frame 4 is separated from the outer frame 5.

As described above, the clamping structure is divided into two different types, i.e., elastic clamping structure and inelastic clamping structure. The elastic clamping structure can enable the protrusion thereof enter into or be released from a corresponding groove (or move close to or away from the outer frame 5) by elastic deformation. Whereas, the inelastic clamping structure cannot have distinct elastic deformation, thus the position of the protrusion is substantially fixed.

In an exemplary embodiment of the present disclosure, the inner frame includes a middle frame 41 located at least in an edge region of a front surface of the inner frame and a back case 42 located at least on a back surface of the inner frame.

Particularly, the inner frame 4 includes a back case 42 and a middle frame 41, the middle frame 41 is disposed corresponding to the edge region of the front surface, and is of a structure similar to a shape like a Chinese character ‘ [symbol] ’ with an opening provided in the center to expose a surface of a target structure; the back case 42 is located on the back surface of the inner frame, and is substantially a flat panel that seals the back surface of the inner frame, and has a protruding side portion 429 arranged at some positions of the edge thereof.

In an exemplary embodiment of the present disclosure, as shown in FIGS. 2b to 5, the inelastic clamping structure between the inner frame 4 and the outer frame 5 includes a first clamping structure, the first clamping structure including:

a first protrusion 11 provided on a side surface 47 of the inner frame 4 and having a first side surface 711 located at the front surface side and a second side surface 712 located at the back surface side, the second side surface 712 being parallel to a front surface 49, and an angle between the first side surface 711 and the second side surface 712 being greater than 0 degree and less than 90 degrees; and

a first groove 51 provided at an inner side of the inner frame 5 for receiving the first protrusion 11, the first groove 51 having a first face 721 at the front surface side and a second face 722 at the back surface side when assembled, the second face 722 being parallel to and in surface contact with the second side surface 712 when assembled.

In an exemplary embodiment of the present disclosure, the outer frame 5 includes a snap-fit portion 59 that is clamped on a front surface (i.e., upper surface) of the middle frame 41 when assembled. In a modification example provided by the present disclosure, as shown in FIG. 2b, a first protrusion 591 disposed on a lower surface of the snap-fit portion 59, a first groove 411 disposed on an upper surface of the middle frame 41, the first protrusion 591 being received in the first groove 411 when assembled and being elastically deformable. Particularly, when the inner frame 4 and the outer frame 5 are assembled together, the first protrusion 591 on the lower surface of the snap-fit portion 59 is squeezed to elastically deform, and then is received in the first groove 411 on the upper surface of the middle frame 41. By cooperation of the first groove 411 and the first protrusion 591, the inner frame 4 and the outer frame 5 can be connected to each other firmly.

In an exemplary embodiment of the present disclosure, in a modification example provided by the present disclosure, as shown in FIG. 2b, a second protrusion 7121 is disposed on the second side surface 712, a second groove 7221 is disposed in the second face 722, the second protrusion 7121 being received in the second groove 7221 when assembled. Particularly, when the inner frame 4 and the outer frame 5 are assembled together, that is, when the first protrusion 11 is inserted into the first groove 51, the second protrusion 7121 on the second side surface 712 is engaged in the second groove 7221 in the second face 722. By cooperation of the second groove 7221 and the second protrusion 7121, the first protrusion 11 may be easily positioned in the first groove 51, so that the assembling operation becomes simple and convenient.

In an exemplary embodiment of the present disclosure, the back case 42 has a side portion 429 located on a side surface of the inner frame, the first protrusion 11 is provided at a side of the side portion 429 facing toward the outer frame 5 when assembled.

Referring to FIGS. 2a to 5, a specific form of the inelastic clamping structure is a first clamping structure that includes a first protrusion 11 provided on a side surface of the inner frame. Wherein, the back case 42 has a side portion 429 provided on a side surface of the inner frame at a position corresponding to the first protrusion 11, the first protrusion 11 may be provided outside of the side portion 429, the reason that the first protrusion 11 is provided on the back case 42 is that the back case 42 has high strength and is not subject to elastic deformation.

In the mean time, a side at the back surface side of the first protrusion 11 is a second side surface 712 parallel to the front surface 49 (a lower side of the first protrusion 11 in FIG. 2a). Accordingly, in the first groove 51 for receiving the first protrusion 11 of the outer frame 5, the second face 722 at the back surface side (the lower surface of the first groove 51 in FIG. 2a) is parallel to the second side surface 712, so as to be able to keep surface contact (such as frictional contact) with the second side surface 712, so that the inner frame is clamp-fixed between the second face 722 and the snap-fit portion 59 to ensure contact stability. By contrast, the first side surface 711 of the first protrusion 11 is inclined with respect to the second side surface 712 to facilitate assembly and disassembly.

In an exemplary embodiment of the present disclosure, an angle between the first side surface 711 and the second side surface 712 (angle a in FIG. 3) is 30 to 60 degrees; the first face 721 is parallel to the second face 722, and the first face 721 has a gap with the first side surface 711 when assembled.

That is to say, referring to FIG. 2a, the first side surface 711 (the upper side of the first protrusion 11 in FIG. 2a) at the front surface side of the first protrusion 11 is disposed inclined at a designated angle with respect to the second side surface 712, and the first face 721 (the upper surface of the first groove 51 in FIG. 2a) at the front surface side of the first groove 51 is parallel to the second face 722, and the first face 721 has a gap with the first side surface 711. The reason to employ the above structure is that the first clamping structure is inelastic, thus referring to FIG. 3, when the first protrusion needs to be snapped into or released from the first groove 51, the inner frame needs to be inclined with respect to the outer frame 5, whereas the first side surface 711 disposed inclined as described above would not touch the first face 721 during this process.

In an exemplary embodiment of the present disclosure, the first groove 51 has a larger depth, and in order to increase the strength of the outer frame 5, the first groove 51 may only be disposed at the first protrusion 11 with reference to FIG. 5; and when the outer frame 5 is formed of wood, the surface other than the first face 721 and the second face 722 may be a gradual slope surface to facilitate processing of wooden product, for example, the outer frame 5 is a wooden frame.

In an exemplary embodiment of the present disclosure, as shown in FIGS. 6-9, the elastic clamping structure between the inner frame 4 and the outer frame 5 includes a second clamping structure located at a side surface of the inner frame, the second clamping structure including:

a first bent portion 21 having a first end 211 and a second end 212, the first end 211 being connected to the middle frame 41;

a second protrusion 12 provided at a side of a second end 212 of the first bent portion 21 facing toward the outer frame 51 when assembled, the second protrusion 12 having a third side surface 713 located at the front surface side and a fourth side surface 714 located at the back surface side, an angle between the third side surface 713 and the fourth side surface 714 being 40 to 90 degrees, an angle between the fourth side surface 714 and the front surface 49 being 0 to 25 degrees; and

a second groove 52 provided at an inner side of the outer frame 5 for receiving the second protrusion 12, the second groove 52 having a third face 723 located at the front surface side and a fourth face 724 located at the back surface side when assembled, the third face 723 being parallel to the third side surface 713 when assembled, the fourth face 724 being parallel to the fourth side surface 714 when assembled.

By elastic deformation of the first bent portion 21, the second protrusion 12 can enter into or be released from the second groove 52.

In an exemplary embodiment of the present disclosure, the first bent portion 21 is formed of a shape-memory material. In this way, the first bent portion 21 is elastically deformable during assembling such that the second protrusion 12 can be engaged in the second groove 52. After the assembling is accomplished, the first bent portion 21 can resume its original shape and last, thereby engaging the second protrusion 12 in the second groove 52 steadily, i.e., bringing the inner frame 4 and the outer frame 5 into secured connection with each other.

That is to say, referring to FIGS. 6 to 9, one form of the elastic clamping structure is a second clamping structure that includes a first bent portion 21 with a first end 211 thereof fixedly disposed (specifically, is connected to the middle frame 41 in the edge region on the front surface of the inner frame, the first bent portion 21 and the middle frame 41 may be an integrated structure), the second protrusion 12 is provided at a second end 212 of the first bent portion 21 (a lower end of a cantilever of the first bent portion 21 in FIG. 6). The first bent portion 21 is formed of an elastic material such as plastic and has a small thickness, thereby being elastically deformable; and by elastic deformation of the first bent portion 21, the second protrusion 12 of the second end 212 can move away from or approach the outer frame 5, so that the second protrusion 12 enters or pops out of the second groove 52.

In an exemplary embodiment of the present disclosure, the angle between the fourth side surface 714 at the back surface side of the second protrusion 12 (the lower side of the second protrusion in FIG. 7) and the front surface 49 (angle b in FIG. 7) and the angle between the third side surface 713 at the front surface side (the upper side of the second protrusion 12 in FIG. 7) and the fourth side surface 714 of the second protrusion 12 both have particular ranges. Thus referring to FIG. 6, when viewed from the side, the second protrusion 12 has a triangular structure with an angle oriented toward the outer frame 5, the shape of the second groove 52 at the inner side of the outer frame 5 matches with this angle of the triangle. Since the second groove 52 has a small depth, it is merely used to receive the end of the second protrusion 12 (i.e., the angle oriented toward the outer frame 5 of the triangle). In this way, when it is necessary to assemble the inner frame with the outer frame 5 or separate the inner frame from the outer frame 5, the second protrusion 12 may snap into the second groove 52 naturally or pop out of the second groove 53 without separate operations.

In an exemplary embodiment of the present disclosure, a height of the second protrusion 12 should be greater than a predetermined gap between the back case 42 and the outer frame 5 plus a mounting tolerance to ensure that the end of the second protrusion 12 can enter the second groove 52.

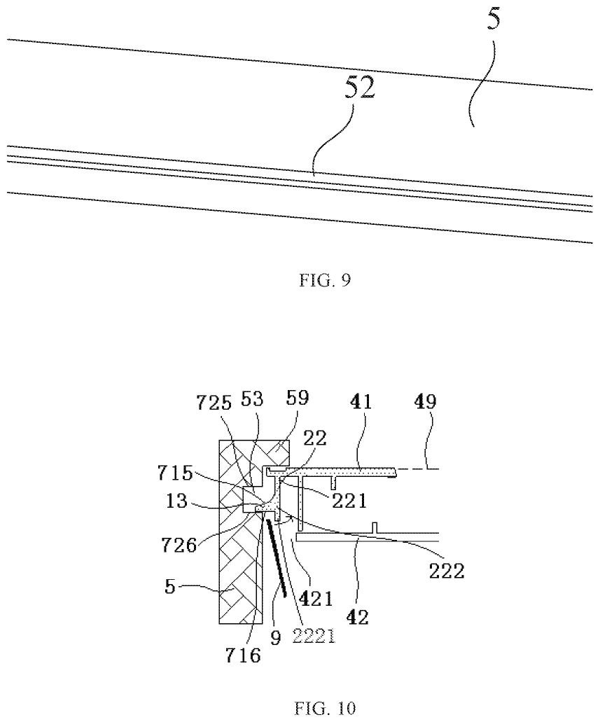

In an exemplary embodiment of the present disclosure, since the second groove 52 is very shallow, it has little influence on the structural strength, thus it may be a continuously extending groove as shown in FIG. 9.

In an exemplary embodiment of the present disclosure, as shown in FIGS. 10 to 13, the elastic clamping structure between the inner frame 4 and the outer frame 5 includes a third clamping structure located on a side surface of the inner frame, the third clamping structure including:

a second bent portion 22 having a first end 221 and a second end 222, the first end 221 being connected to the middle frame 41;

a third protrusion 3 disposed at a side of the second end 222 of the second bent portion 22 facing toward the outer frame 51 when assembled, the third protrusion 13 having a fifth side surface 715 at the front surface side and a sixth side surface 716 at the back surface side, the sixth side surface 716 being parallel to the front surface 49; and

a third groove 53 disposed at the inner side of the outer frame 5 and configured to receive the third protrusion 13, the third groove 53 having a fifth face 725 at the front surface side and a sixth face 726 at the back surface side when assembled, the sixth face 726 being parallel to and in surface contact with the sixth side surface 716 when assembled, the fifth face 725 has a gap with the fifth side surface 715 when assembled.

By elastic deformation of the second bent portion 22, the third protrusion 13 can enter into or be released from the third groove 53.

As shown in FIG. 10, a first opening 421 is provided at a portion of the back case 42 corresponding to the second bent portion 22 (i.e., a position right below the second bent portion 22).

In an exemplary embodiment of the present disclosure, the second bent portion 22 is formed of a shape-memory material. In this way, the second bent portion 22 is elastically deformable during assembly, such that the third protrusion 13 can be engaged in the third groove 53. After the assembling is accomplished, the second bent portion 22 can resume its original shape and last, thereby engaging the third protrusion 13 in the third groove 53, i.e., bringing the inner frame 4 and the outer frame 5 into secured connection with each other.

Referring to FIGS. 10 to 13, another form of the elastic clamping structure is a third clamping structure that includes a second bent portion 22, with a first end 221 thereof fixedly disposed (specifically, is connected to the middle frame 41 in the edge region on the front surface of the inner frame, the second bent portion 22 and the middle frame 41 may be an integrated structure), the third protrusion 13 is provided outside a second end 222 of the second bent portion 22 (a lower end of a cantilever of the second bent portion 22 in FIG. 10). The second bent portion 22 is formed of an elastic material such as plastic and has a small thickness, thereby being elastically deformable; and by elastic deformation of the second bent portion 22, the third protrusion 13 of the second end 222 thereof can enter into or be released from the third groove 53 at an inner side of the outer frame 5.

In an exemplary embodiment of the present disclosure, the sixth side surface 716 at the back surface side of the third protrusion 13 (the lower side of the third protrusion in FIG. 10) and the sixth face 726 at the back surface side of the third groove 53 (the lower surface of the third groove 53 in FIG. 10) are both parallel to the front surface 49 to form a stable surface contact therebetween and clamp the inner frame between the sixth face 726 and the snap-fit portion 59; and a gap exists between the fifth side surface 715 at the front surface side (the upper side of the third protrusion 13 in FIG. 10) and the fifth face 725 at the front surface side of the third groove 53 (the upper surface of the third groove 53 in FIG. 10) of the third protrusion to facilitate popping of the third protrusion 13 out of the third groove 53. As can be seen, the specific form of the fifth face 725 is not limited, which may be, for example, an arc surface, or a flat surface, etc., as shown in FIG. 10.

In an exemplary embodiment of the present disclosure, referring to FIG. 6 and FIG. 10, the middle frame 41 further has a portion extending longitudinally at the inner side of the first bent portion 21 and the second bent portion 22, this portion is not a bent portion but a portion to form a semi-closed space with the back case 42 for providing a target structure (such as a display unit).

As shown in FIG. 10, a first opening 4211 is provided at a position corresponding to the third protrusion 13 on the back case 42 on the back surface of the inner frame. In this way, referring to FIG. 10, when it is necessary to separate the inner frame 4 from the outer frame 5, the second end 222 of the second bent portion 22 may be toggled using a tool 9 through the first opening 421 (in order to facilitate drive of the second bent portion 22 by the tool 9, a protruding portion 2221 protruding downwardly may be provided at the second end 222 of the second bent portion 22, that is, the protruding portion 2221 protruding from the sixth side surface 716 toward the first opening 421), so that the third protrusion 13 pops out of the third groove 53. It is to be understood that the size of the first opening 421 should be enough to allow insertion of the tool 9 therein.

In an exemplary embodiment of the present disclosure, the third groove 53 has a relatively large depth, in order to increase the strength of the outer frame 5, the third groove 53 may only be provided at a position corresponding to the third protrusion 13 with reference to FIG. 12; and when the outer frame 5 is formed of wood, the surface other than the fifth face 725 and the sixth face 726 may be a gradual slope surface to facilitate processing of a wooden product (for example, the outer frame 5 is a wooden frame).

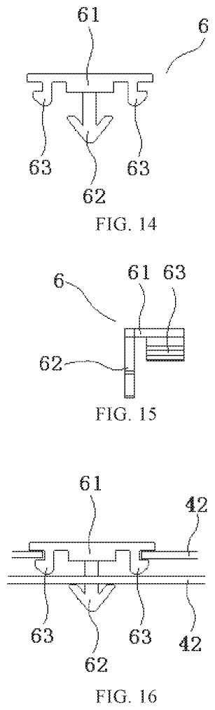

In an exemplary embodiment of the present disclosure, as shown in FIG. 14 and FIG. 15, the inner frame 4 further includes a closure member 6, the closure member 6 being formed of an elastic material and including:

a base 61 for closing the first opening 421;

a major protrusion 62 disposed on one side of the base 62, the major protrusion 62 having an arrow structure disposed at an end away from the base 61, a dimension of the arrow structure in a direction perpendicular to a height direction of the major protrusion 62 may be increased or reduced through elastic deformation; and

a minor protrusion 63 disposed on the same side of the base 61 as the major protrusion 62, the minor protrusion 63 having a curved portion disposed at an end away from the base 61.

In an exemplary embodiment of the present disclosure, as shown in FIG. 13, the back case 42 has a second opening 422 into which the arrow structure of the major protrusion 62 is inserted through elastic deformation, the curved portion of the minor protrusion 63 being used to clamp the back case between the minor protrusion 63 and the base 61.

In order to prevent the first opening 421 from affecting the overall appearance of the frame of the electronic device, a separate closure member 6 may be disposed to close the first opening 421. When the inner frame needs to be separated from the outer frame 5, the closure member 6 may be detached to expose the first opening, thereby allowing entry of the tool 9.

Particularly, referring to FIGS. 14 to 16, the closure member 6 may be formed of an elastic material such as silica gel, the closure member 6 including: a base 61 for closing the first opening 421, a major protrusion 62 (the number may be, for example, one) having an arrow structure at end portion thereof is disposed at one side of the base 61; and a minor protrusion 63 (the number may be, for example, two) having a hook structure (i.e., a bent portion) at an end portion thereof. Referring to FIG. 16, the arrow structure at the end portion of the major protrusion 62 may be contracted through elastic deformation, thereby being inserted into a second opening 422 on the back case 42 and then extended after insertion into the second opening 422, a wall of the back case 42 on the edge of the first opening 421 may be clamped between the hook structure of the minor protrusion 63 and the base 61 to secure the closure member 6, such that the base 61 blocks off the first opening 421. Since the closure member 6 is formed of elastic material, it may be detached from the back case 62 through deformation of the arrow structure and the hook structure.

Of course, the closure member 6 may also employ other different forms as long as it can be detachably mounted on the inner frame 4 and block off the first opening 421.

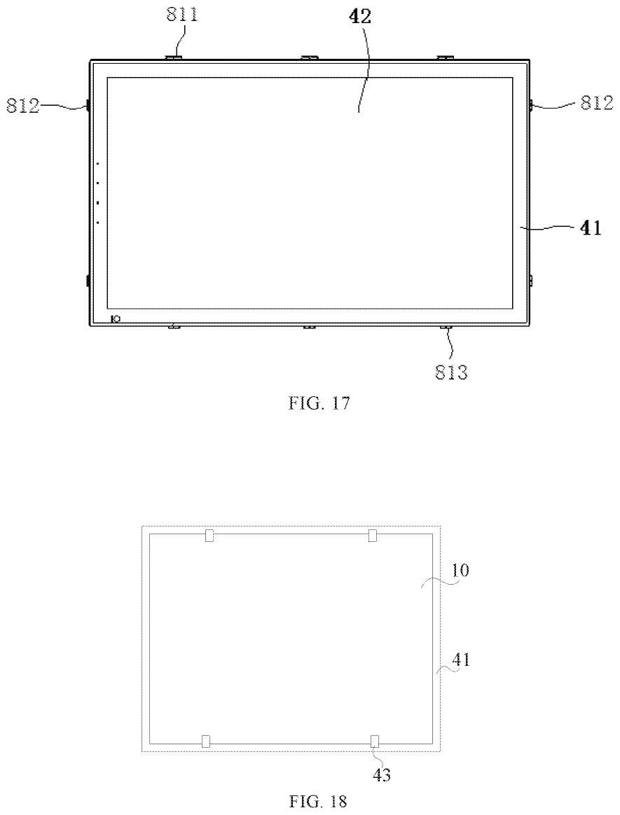

In an exemplary embodiment of the present disclosure, as shown in FIG. 17, a side edge of the inner frame 4 includes a first side edge 811 (the upper side of the inner frame 4 in FIG. 17), two second side edges 812 (the left side and right side of the inner frame 4 in FIG. 17) connected to the two ends of the first side edge 811, respectively, and a third side edge 813 (the lower side of the inner frame 4 in FIG. 17) connected between the two second side edges 812 and disposed opposite the first side edge 811. The first clamping structure is disposed on the first side edge 811; the second clamping structure is disposed on the second side edge 812; the third clamping structure is disposed on the third side edge 813.

That is to say, referring to FIG. 17, the first clamping structure and the third clamping structure may be disposed on two opposite side edges of the inner frame 4 (the first side edge 811 in an upper portion and the third side edge 813 in a lower portion), respectively, whereas the second clamping structure is disposed on the other two side edges of the inner frame 4 (the two second side edges 812 at the left and right sides). Of course, a plurality of clamping structures of the same type may be disposed on each side edge of the inner frame 4. In an exemplary embodiment of the present disclosure, the first clamping structure is inelastic, thus the inner frame 4 needs to be tilted with respect to the outer frame 5 in a particular manner to facilitate snap-in and release, thus all first clamping structures should be disposed on the same side edge; whereas the third clamping structure needs to be released by toggle of the tool 9, thus for easy operation, the third clamping structure should be disposed on a side edge opposite to the first clamping structure; since the second protrusion 112 of the second clamping structure is snapped into the second groove 52 by a small depth, it can be easily snapped in or released upon a force, thus the second clamping structure should be disposed on a side edge different from the first clamping structure and the third clamping structure.

Of course, it should be understood that the middle frame 41 and the back case 42 may be connected to each other by adhesion or clamping, for example, when the target structure is a display unit, the middle frame 41 and the back case 42 may be two portions of the outer case of the display unit, and fix the display unit therein after being engaged together.

Of course, it should be understood that it is suitable that the snap-fit portion 59 is disposed at a position on the edge of the front surface of the middle frame 41, but it is preferably disposed at least at a position corresponding to the first protrusion 11, the first protrusion 13, and more preferably referring to FIG. 1, the snap-fit portion 59 is formed as a closed “loop” to ensure stability of the snap-fitting.

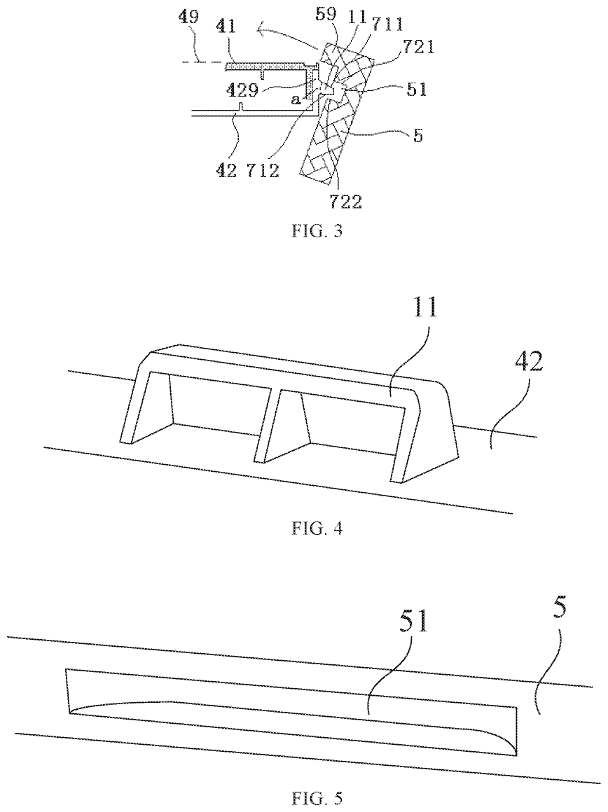

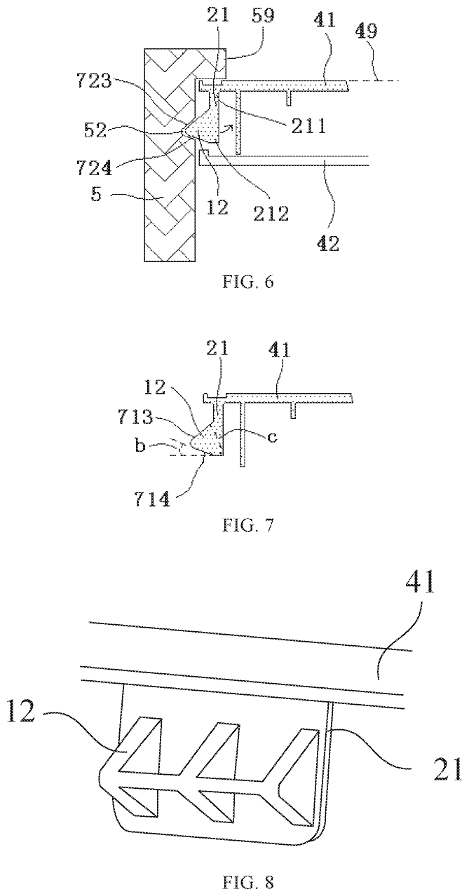

Of course, it should be understood that for convenient demolding and increased strength, a person skilled in the art may dispose structures such as transitional circular corners, recesses and reinforcing ribs in the protrusions, grooves and bent portions, and such structures may result in throughholes and recesses and the like in the first side surface 711 to the sixth side surface 716, as shown in FIG. 4, FIG. 8.

In an exemplary embodiment of the present disclosure, as shown in FIG. 18, the edge of the display unit 10 may be fixed on the middle frame 41 via a pressing piece 43. Particularly, after the middle frame 41 is put in place, the display unit 10 is placed on the middle frame 41, at this time, the edge of the display unit 10 and the edge of the middle frame 41 abut against each other, an end of the pressing piece 43 is placed on a non-display side of the display unit, and the other end of the pressing piece 43 is fixed on the middle frame 41 via a fastener or a magnetic member, such that the display unit 10 is reliably fixed on the middle frame 41. It is to be understood that the number and position of the pressing piece 43 may be arbitrarily set as desired.

In an exemplary embodiment of the present disclosure, as shown in FIG. 19, the middle frame 41 may be formed of a first middle frame 412 and a second middle frame 413, the first middle frame 412 and the second middle frame 413 being partially overlapping with each other, and an end of the middle frame 413 protrudes out of an end of the first middle frame 412. Particularly, the middle frame 41 has a dual-layer construction, with one layer being the first middle frame 412, and the other being the second middle frame 413. The first middle frame 412 has a substantially L-shape, and the second middle frame 413 has a flat-plate shape, as shown in FIG. 19, a horizontal portion of the L-shaped first middle frame 412 and an end portion of the second middle frame 413 partially overlap with each other, and the other end portion of the middle frame 413 protrudes from the horizontal portion of the first middle frame to be exposed. The first middle frame 412 may be formed of a material different from the second middle frame 413, so that better protection can be provided for the display unit while ensuring certain rigidity.

In an exemplary embodiment of the present disclosure, as shown in FIG. 19, the middle frame 41 and the back case 42 may enclose a space 45 having an opening 44 and in which the display unit 10 is received. Particularly, the space 45 receiving the display unit 10 is enclosed by the walls of the middle frame 41 and the back case 42, and a display surface of the display unit 10 is exposed from the middle frame 4 that is formed of the middle frame 41 and the back case 42.

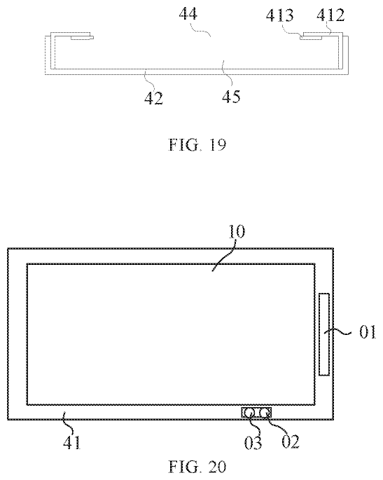

In an exemplary embodiment of the present disclosure, as shown in FIG. 1 (the front view) and FIG. 20 (the back view), the middle frame 41 has a rectangular shape, a microphone 01 may be disposed on a short edge of the middle frame 41, and an infrared sensor 02 and an light sensor 03 are disposed on a long edge of the middle frame 41. Particularly, as shown in FIG. 20, a microphone 01 is disposed on a vertical edge of the rectangular middle frame 41, and an infrared sensor 02 and a light sensor 03 are disposed on a horizontal edge of the rectangular middle frame 41. Particularly, a groove is disposed on a vertical edge of the rectangular middle frame 41, the microphone 01 is received in the groove, so that the periphery of the microphone 01 is protected by the middle frame 41, and by means of the microphone 01 a sound of the electronic device may be output. On or more grooves are disposed on the horizontal edge of the rectangular middle frame 41, the infrared sensor 02 and the light sensor 03 are respectively received in the grooves, so that the periphery of the infrared sensor 02 and the light sensor 03 are protected by the middle frame 41, and by means of the infrared sensor 02 an external control signal may be received, and by means of the light sensor 03 the electronic device may easily sense external environment data, so that the electronic device becomes more intelligent, for example, the intensity of illumination, contrast and the like may be adjusted based on the external environment data sensed by the light sensor 03.

In an exemplary embodiment of the present disclosure, the electronic device may be any product with a display function, including mobile phone, tablet computer, TV set, displayer, laptop computer, digital photo frame and navigator, It should be understood that above embodiments are just examples for illustrating the principle of the invention, however, the invention is not limited thereto. Various modifications and variations can be made by a person skilled in the art without departing from the spirit and the scope of the present invention. These modifications and variations should be considered to be within protection scope of the present invention.

1-25. (canceled)

26. An electronic device, comprising:
a frame; and
a display unit surrounded by the frame on a periphery thereof,
wherein the frame comprises:
an inner frame having a front surface, a back surface opposite the front surface, and a side surface connected between the front surface and the back surface; and
an outer frame arranged around the side surface of the inner frame, the inner frame and the outer frame being detachably engaged through at least one clamping structure.

27. The electronic device according to claim 26, wherein
each of the at least one clamping structure comprises a protrusion disposed on the side surface of the inner frame and a groove disposed at an inner side of the outer frame and configured to receive the protrusion.

28. The electronic device according to claim 27, wherein
the at least one clamping structure comprises an elastic clamping structure and an inelastic clamping structure, wherein
the elastic clamping structure enables the protrusion of the elastic clamping structure to enter into or be released from a corresponding groove through elastic deformation.

29. The electronic device according to claim 28, wherein
the inner frame comprises a middle frame located in an edge region of the front surface of the inner frame and a back case located on the back surface of the inner frame.

30. The electronic device according to claim 29, wherein
the inelastic clamping structure comprises a first clamping structure having:
a first protrusion disposed on the side surface of the inner frame, having a first side surface on a front surface side and a second side surface on a back surface side, the second side surface being parallel to the front surface, an angle between the first side surface and the second side surface being greater than 0 degree and less than 90 degrees; and
a first groove disposed at the inner side of the outer frame and configured to receive the first protrusion, the first groove having a first face at the front surface side and a second face at the back surface side when assembled, the second face being parallel to and in surface contact with the second side surface when assembled.

31. The electronic device according to claim 30, wherein
the angle between the first side surface and the second side surface is 30 to 60 degrees, and
the first face is parallel to the second face and has a gap with the first side surface when assembled.

32. The electronic device according to claim 30, wherein
the back case comprises a side portion located on a side surface of the inner frame, the first protrusion being disposed on a side of the side portion facing the outer frame when assembled.

33. The electronic device according to claim 30, wherein
the outer frame comprises a snap-fit portion that snaps into an upper surface of the middle frame when assembled.

34. The electronic device according to claim 33, wherein
a first convex portion is provided on a lower surface of the snap-fit portion, and a first concave portion is provided in an upper surface of the middle frame, the first convex portion being received in the first concave portion when assembled, the first convex portion being elastically deformable.

35. The electronic device according to claim 31, wherein
a second convex portion is provided on the second side surface, and a second concave portion is provided in the second face, the second convex portion being received in the second concave portion when assembled.

36. The electronic device according to claim 30, wherein
the elastic clamping structure comprises a second clamping structure located on the side surface of the inner frame, the second clamping structure comprising:
a first bent portion having a first end and a second end, the first end being connected to the middle frame;
a second protrusion that is disposed at a side of the second end of the first bent portion facing the outer frame when assembled, the second protrusion having a third side surface on the front surface side and a fourth side surface on the back surface side, an angle between the third side surface and the fourth side surface being 40 to 90 degrees, an angle between the fourth side surface and the front surface being 0 to 25 degrees; and
a second groove that is disposed at the inner side of the outer frame and configured to receive the second protrusion, the second groove having a third face on the front surface side and a fourth face on the back surface side when assembled, the third face being parallel to the third side surface when assembled, the fourth face being parallel to the fourth side surface when assembled.

37. The electronic device according to claim 36, wherein
the first bent portion is elastically deformable and formed of a shape-memory material.

38. The electronic device according to claim 36, wherein
the elastic clamping structure comprises a third clamping structure located on the side surface of the inner frame, the third clamping structure comprising:
a second bent portion having a first end and a second end, the first end being connected to the middle frame
a third protrusion that is disposed on a side of second end of the second bent portion facing the outer frame when assembled, the third protrusion having a fifth side surface at the front surface side and a sixth side surface at the back surface side, the sixth side surface being parallel to the front surface; and
a third groove that is disposed at the inner side of the outer frame and configured to receive the third protrusion, the third groove having a fifth face at the front surface side and a sixth face at the back surface side when assembled, the sixth face being parallel to and in surface contact with the sixth side surface when assembled, the fifth face having a gap with the fifth side surface when assembled.

39. The electronic device according to claim 38, wherein
a first opening is disposed at a portion of the back case corresponding to the second bent portion, the second end of the second bent portion comprises a protruding portion protruding from the sixth side surface toward the first opening.

40. The electronic device according to claim 39, further comprising a closure member, the closure member being formed of an elastic material and comprising:
a base configured to close the first opening;
a major protrusion disposed on one side of the base, the major protrusion having an arrow structure disposed at an end away from the base, a dimension of the arrow structure in a direction perpendicular to a height direction of the major protrusion being increased or reduced through elastic deformation; and
a minor protrusion disposed on a same side of the base as the major protrusion, the minor protrusion having a curved portion disposed at an end away from the base.

41. The electronic device according to claim 40, wherein
the back case has a second opening into which the arrow structure of the major protrusion is inserted through elastic deformation, so that the back case is sandwiched between the curved portion of the minor protrusion and the base.

42. The electronic device according to claim 38, wherein
a side edge of the inner frame comprises a first side edge, two second side edges connected to two ends of the first side edge, respectively, and a third side edge connected between the two second side edges and disposed opposite the first side edge; wherein
the first clamping structure is disposed at the first side edge;
the second clamping structure is disposed at the second side edge; and
the third clamping structure is disposed at the third side edge.

43. The electronic device according to claim 26, wherein
the inner frame is formed of a plastic or metal material, and the outer frame is formed of wood or plastic material.

44. The electronic device according to claim 26, wherein
the inner frame comprises a middle frame located in an edge region of the front surface of the inner frame and a back case located on the back surface of the inner frame, and an edge of the display unit is fixed to the middle frame via a pressing piece.

45. The electronic device according to claim 44, wherein
the middle frame is formed of a first middle frame and a second middle frame, the first middle frame being partially overlapping with the second middle frame, and one end portion of the second middle frame protruding from one end portion of the first middle frame.
